(19) United States
(12) Patent Application Publication
(10) Pub. No.: US 2015/0270310 A1
(43) Pub. Date: Sep. 24, 2015

(54) METHOD OF MANUFACTURING SOLID-STATE IMAGE SENSOR

(71) Applicant: CANON KABUSHIKI KAISHA, Tokyo (JP)

(72) Inventor: Satoshi Hirayama, Yokohama-shi (JP)

(21) Appl. No.: 14/641,695

(22) Filed: Mar. 9, 2015

(30) Foreign Application Priority Data
Mar. 18, 2014 (JP) 2014-055617

(51) Int. Cl. H01L 27/146

(52) U.S. Cl. CPC H01L 27/14692; H01L 27/14698

(57) ABSTRACT

A method of manufacturing a solid-state image sensor which forms a wiring structure including a plurality of wiring layers on a semiconductor substrate including a photoelectric conversion unit, the method comprising steps of depositing a silicon-containing film which contains hydrogen on an uppermost wiring layer out of the plurality of wiring layers, and irradiating the silicon-containing film with UV light.

### BACKGROUND OF THE INVENTION

1. Field of the Invention

The present invention relates to a method of manufacturing a solid-state image sensor.

2. Description of the Related Art

It is possible to reduce a dark current and noise by terminating the Si dangling bond of an Si—SiO₂ interface generated in processing a solid-state image sensor. In Japanese Patent Laid-Open No. 2010-205951, the first stress liner film and the second stress liner film each using a silicon nitride film are formed on the side spacer of a transistor in order to increase the operating speed of the transistor. At this time, hydrogen is supplied using the first stress liner film, hydrogen in the silicon nitride film is dissociated, and the Si dangling bond is terminated with hydrogen to reduce noise. Furthermore, the second stress liner film is UV-cured and hydrogen in the silicon nitride film is dissociated to increase a stress.

### SUMMARY OF THE INVENTION

A method described in Japanese Patent Laid-Open No. 2010-205951 cannot reduce an Si dangling bond which is formed in a stress liner film formation step or its subsequent step, and limits an effect of reducing a dark current and noise. To solve this, one aspect of the present invention provides a technique of terminating the Si dangling bond generated during a process, and reducing the generation of the dark current and noise.

According to some embodiments, a method of manufacturing a solid-state image sensor which forms a wiring structure including a plurality of wiring layers on a semiconductor substrate including a photoelectric conversion unit is provided. The method comprising steps of depositing a silicon-containing film which contains hydrogen on an uppermost wiring layer out of the plurality of wiring layers, and irradiating the silicon-containing film with UV light.

Further features of the present invention will become apparent from the following description of exemplary embodiments (with reference to the attached drawings).

### BRIEF DESCRIPTION OF THE DRAWINGS

FIGS. 1A to 1D show views for explaining a solid-state image sensor manufacturing process according to an embodiment of the present invention;

FIG. 2 is a graph for explaining a dark current reduction effect by UV irradiation according to the embodiment of the present invention; and

FIG. 3 is a graph showing the transmittance of UV light with respect to a passivation film in the relationship between a film thickness and a wavelength according to the embodiment of the present invention.

### DESCRIPTION OF THE EMBODIMENTS

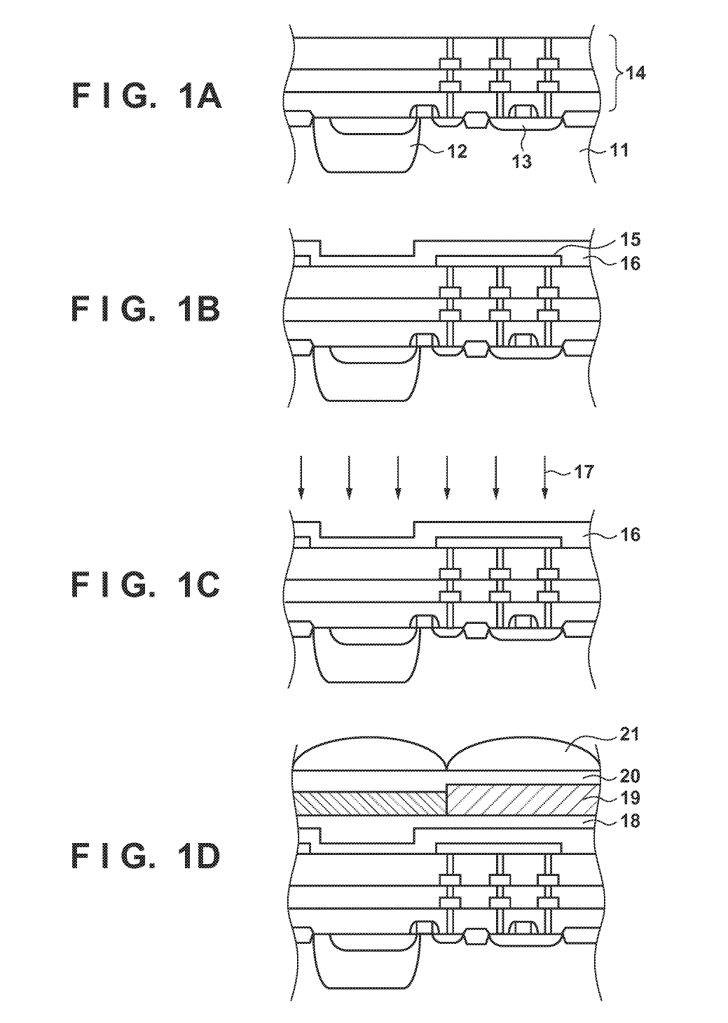

An embodiment of the present invention will be described below with reference to the accompanying drawings. FIG. 1 shows views for explaining a method of manufacturing a solid-state image sensor according to the embodiment of the present invention. This embodiment will be described taking a CMOS image sensor as an example.

FIG. 1A shows the structure of the solid-state image sensor before depositing a passivation film according to this embodiment. In FIG. 1A, a photoelectric conversion unit 12 which photoelectrically converts incident light to obtain signal charges and a pixel transistor unit 13 which outputs the charges generated by the photoelectric conversion unit 12 are formed on a semiconductor substrate 11. The charges output from the pixel transistor unit 13 are output via a wiring structure 14. The wiring structure 14 is formed by a plurality of aluminum wiring layers, plugs such as tungsten plugs, and interlayer dielectric films.

FIG. 1B shows a state in which aluminum wiring 15 is formed on the wiring structure 14 of the solid-state image sensor shown in FIG. 1A and a passivation film 16 is further formed on the aluminum wiring 15 as a silicon-containing film. The passivation film 16 is formed, as shown in FIG. 1B, to cover the uppermost aluminum wiring 15 and the interlayer dielectric films included in the wiring structure 14, and can be formed by depositing a silicon nitride film by, for example, plasma CVD using an SiH₄ gas and an NH₃ gas. The passivation film 16 is formed to have the thickness of 200 nm to 2,000 nm. Many Si—H groups and N—H groups exist in the deposited film. The Si dangling bonds of the photoelectric conversion unit 12 and the pixel transistor unit 13 can be terminated with hydrogen by performing annealing in a hydrogen atmosphere at about 400° C. after the formation of the passivation film.

Next, FIG. 1C shows a state in which the passivation film is irradiated with UV light 16. Irradiation with UV light 17 is performed using, for example, a dielectric barrier discharge excimer lamp after the passivation film 16 undergoes annealing. The UV light used for irradiation has, for example, a wavelength of 172 nm and an energy of 7.2 eV. The energy of UV light shown in this example is larger than an Si—H bounding energy of 3.1 eV and an N—H bounding energy of 4.0 eV. Therefore, hydrogen of the Si—H groups and the N—H groups contained in the passivation film is dissociated, and the Si dangling bonds of the photoelectric conversion unit 12 and the pixel transistor unit 13 which could not be terminated in the aforementioned annealing can be terminated with hydrogen. This makes it possible to achieve further reductions in a dark current and noise. After the UV irradiation, a planarizing layer 18, an on-chip color filter 19, a planarizing layer 20, and microlenses 21 are further formed on the protective film 16, as shown in FIG. 1D.

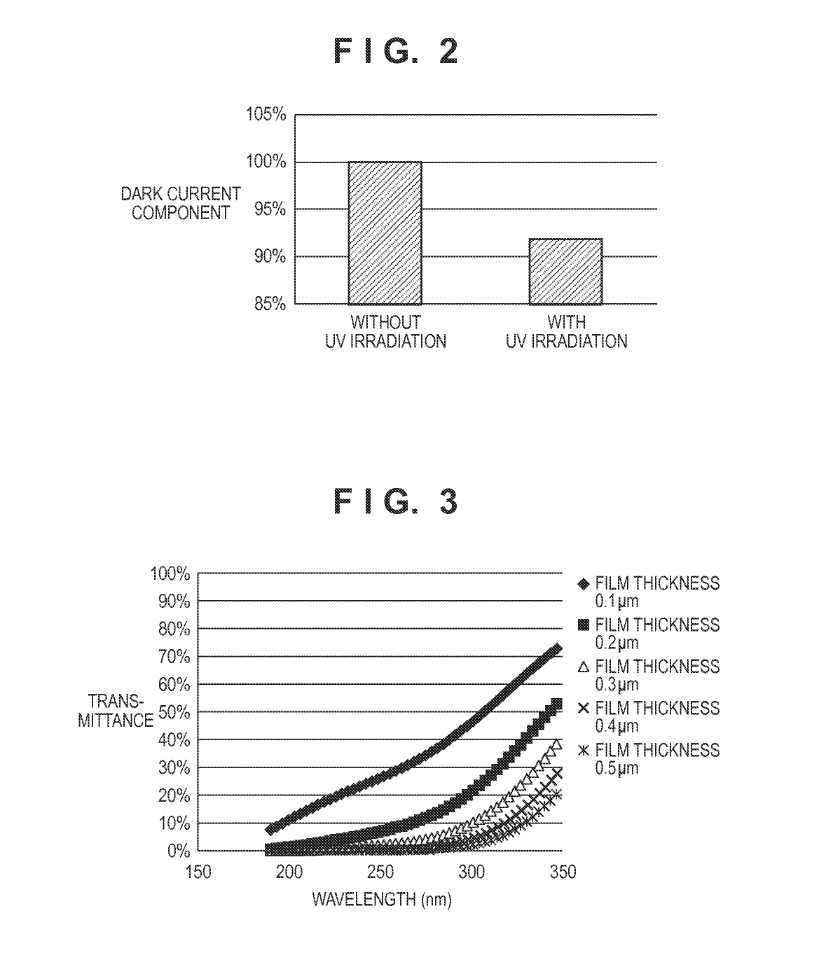

In the embodiment described with reference to FIG. 1C, the passivation film 16 is irradiated with UV light. The effect of UV light irradiation in reducing the dark current will be described with reference to FIG. 2. FIG. 2 is a graph showing dark current components compared when UV light irradiation is performed and when UV light irradiation is not performed after the formation of the passivation film 16. The left side of FIG. 2 shows the dark current when UV irradiation is not performed. The right side of FIG. 2 shows the ratio of the dark current when UV irradiation is performed, assuming that the percentage of the dark current on the left side of FIG. 2 is 100%. On the right side of FIG. 2, the dark current component is reduced to about 92% by performing UV irradiation. As described above, it has been found that the dark current component is reduced by adding a UV irradiation step as compared with a case without any UV irradiation step.

It is also possible to perform an O₂ plasma process in UV irradiation. Since UV light generated in O₂ plasma has a wavelength of 130 nm and an energy of 9.5 eV, the same effect can be obtained as an excimer lamp. Note that the band gap of the silicon nitride film falls within a range of 4.0 eV to 5.1 eV, and is smaller than that of UV light with the wavelength of 172 nm and the energy of 7.2 eV or UV light with the wavelength of 130 nm and the energy of 9.5 eV. Therefore, this UV light cannot be transmitted through the silicon nitride film. In a noise reduction method according to this embodiment, the passivation film may have the thickness through which UV irradiation light cannot be transmitted and UV irradiation light has an energy enough to dissociate hydrogen in the passivation film.

FIG. 3 is a graph showing the wavelength of UV light and the transmittance of UV light with respect to the thickness of the aforementioned passivation film. Note that the dark current may increase because of the disconnection of Si—H bonds in, for example, the photoelectric conversion unit 12 and the pixel transistor unit 13 as an influence of transmission of UV light. Therefore, the thickness of the passivation film through which UV light is less likely to be transmitted and the wavelength of UV light need to be selected appropriately. According to a result in FIG. 3, the transmittance is almost 0% when the wavelength is 200 nm under the condition that the film thickness is 0.2 μm (200 nm) or more. In contrast to this, the transmittance is not 0% even when the wavelength is 200 nm under the condition that the film thickness is 0.1 μm. Therefore, it is found that the dark current can effectively be reduced when both conditions that the thickness of the passivation film is 200 nm or more and the wavelength of UV light is 200 nm or less are satisfied. Furthermore, the passivation film may have a larger thickness because the amount of hydrogen contained increases as the passivation film becomes thicker.

Note that the thickness of the passivation film may become smaller than 200 nm from a viewpoint of the optical design of the solid-state image sensor. In such a case, however, it is possible to reduce the dark current by performing UV light irradiation to an extent in which a problem caused by the influence of UV light transmission does not become obvious by, for example, shortening the wavelength.

In the description of FIG. 1, UV irradiation is performed after annealing. It is possible, however, to obtain the same effect even when UV irradiation is performed before annealing. In this case, annealing facilitates the diffusion of dissociated hydrogen, and thus a higher noise reduction effect can be obtained. The same effect can also be obtained when a passivation film structure has a two-layer structure in which a silicon nitride film is deposited on a silicon oxynitride film or a three-layer structure in which the silicon oxynitride films are deposited on the upper and the lower surfaces of the silicon nitride film. Furthermore, the same effect can also be obtained when the passivation film is shaped like a lens which acts as an inner-layer lens.

In this embodiment described above, the passivation film containing hydrogen is deposited on the solid-state image sensor, and annealing and UV light irradiation are performed. This makes it possible to terminate the Si dangling bond of an Si—SiO₂ interface generated during a process, and reduce the generation of the dark current and noise.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2014-055617, filed Mar. 18, 2014, which is hereby incorporated by reference herein in its entirety.

What is claimed is:

1. A method of manufacturing a solid-state image sensor which forms a wiring structure including a plurality of wiring layers on a semiconductor substrate including a photoelectric conversion unit, the method comprising steps of:
depositing a silicon-containing film which contains hydrogen on an uppermost wiring layer out of the plurality of wiring layers; and
irradiating the silicon-containing film with UV light.

2. The method according to claim 1, further comprising a step of performing annealing of the silicon-containing film.

3. The method according to claim 2, wherein the annealing is performed before the step of irradiating the silicon-containing film with the UV light.

4. The method according to claim 1, wherein in the step of depositing, the silicon-containing film is deposited as a silicon nitride film by plasma CVD.

5. The method according to claim 1, wherein an energy of the UV light is larger than a band gap of the silicon-containing film.

6. The method according to claim 1, wherein a wavelength of the UV light is not more than 200 nm.

7. The method according to claim 1, wherein a thickness of the silicon-containing film is not less than 200 nm.

8. The method according to claim 1, wherein a wavelength of the UV light is not more than 200 nm and a thickness of the silicon-containing film is not less than 200 nm.

9. The method according to claim 1, wherein the silicon-containing film is formed to cover the uppermost wiring layer and an uppermost interlayer dielectric film included in the wiring structure.
